(19) United States
(12) Patent Application Publication
(10) Pub. No.: US 2012/0205778 A1
(43) Pub. Date: Aug. 16, 2012

(54) PACKAGE STRUCTURE AND METHOD FOR MANUFACTURING THE SAME

(76) Inventors: Yuan-Tai LAI, Hsinchu (TW); Jeng-Gong DUH, Hsinchu (TW); Yu-Huei LEE, Hsinchu City (TW); Ke-Horng CHEN, Hsinchu City (TW); Kang SHENG, Hsinchu Science Park (TW); Tsung-Chan WU, (US)

(21) Appl. No.: 13/111,383

(22) Filed: May 19, 2011

(30) Foreign Application Priority Data
Feb. 10, 2011 (TW) 100104395

(51) Int. Cl. H01L 29/02; H01L 21/50

(52) U.S. Cl. 257/531; 257/532; 257/536; 438/3; 257/528; 257/738; 257/E29.002; 257/E21.499

(57) ABSTRACT

The present invention relates to a package structure and method for manufacturing the same. The package structure can minimize the area of the circuit board used for packaging, by stacking a passive element directly on a chip. The disclosed package structure comprises: a circuit board having a first surface, where a plurality of first connecting pads being disposed thereon; a chip unit having an active surface, a non-active surface and a plurality of conductive vias, while a plurality of second connecting pads and a plurality of electric pads being disposed on the active surface, and a plurality of third connecting pads being disposed on the non-active surface; a plurality of solder balls electrically connected with the first connecting pads and the second connecting pads; and a passive element being electrically connected with the third connecting pads. The passive element and the chip unit both electrically connect to the chip unit.

### CROSS REFERENCE TO RELATED APPLICATION

This application claims the benefits of the Taiwan Patent Application Serial Number 100104395, filed on Feb. 10, 2011, the subject matter of which is incorporated herein by reference.

### BACKGROUND OF THE INVENTION

1. Field of the Invention

The present invention relates to a package structure and method for manufacturing the same, more particularly, to a thin and stacked-type three-dimensional package structure, capable of solving the problem of occupying too much circuit board area while a passive element being packaged on the circuit board, of minimizing the area of the circuit board used for packaging, and of increasing the packaging density.

2. Description of Related Art

Electronic device becomes more and more delicate and sophisticated, along with the rapid progressing of technology, such as the tablet personal computer or the smartphone, they have been proposed to the market miscellaneously. An electronic device must to contained multi-functions, to meet the different requirement of the customer.

For meeting the different requirement of the customer, more and more chips must be integrated with the circuit board embedded inside the electronic device. For example, a wire-less communication chip must be installed on the circuit board, for providing the wireless internet-access function. In addition, if the video-related function is required, a video-processing chip must also be installed on the circuit board. In addition to the number of chips must be installed on the circuit board, certain number of passive elements, such as a resistor, an inductor, or a capacitor, must also be installed on the circuit board.

In the present industry, a passive element, such as a resistor, an inductor, or a capacitor, is mounted on the circuit board directly with the surface mounted technology (SMT). However, in opposite to the trend of minimization of the size of the electronic device, the passive element mounted with the surface mounted technology will occupy a certain amount of circuit board area. As a result, when the number of the passive element to be mounted is increasing, most of the circuit board surface will be occupied by these passive elements. Thus, the size of the electronic device cannot be easily minimized.

Therefore, a package structure capable of solving the problem of occupying too much circuit board area while a passive element being packaged on the circuit board, of minimizing the area of the circuit board used for packaging, and of increasing the packaging density is required by the industry.

### SUMMARY OF THE INVENTION

The object of the present invention is to provide a package structure, capable of stacking a passive element directly onto the chip (i.e. integrating the passive element to the chip with the space above the rear side of the chip), instead of the conventional packaging structure, which the passive element being disposed on the circuit board. With this novel packaging structure, the problem of occupying too much circuit board area while a passive element being packaged on the circuit board can be solved. In addition, the area of the circuit board used for packaging can be minimized. Moreover, with proper adjustment, the limitation raised by directly stacking the passive element onto the circuit board can also be resolved.

To achieve the object, the package structure of the present invention comprises: a circuit board having a first surface, where a plurality of first connecting pads being disposed thereon; a chip unit having an active surface, a non-active surface and a plurality of conductive vias, while a plurality of second connecting pads and a plurality of electric pads being disposed on the active surface, and a plurality of third connecting pads being disposed on the non-active surface; wherein the plurality of conductive vias penetrates the chip unit and is electrically connected with the plurality of second connecting pads and the plurality of third connecting pads respectively; a plurality of solder balls electrically connected with the plurality of first connecting pads and the plurality of second connecting pads; and a passive element being disposed on the non-active surface of the chip unit, and electrically connected with the plurality of third connecting pads; wherein the passive element is electrically connected with the chip unit through the plurality of third connecting pads, the plurality of conductive vias, and the plurality of electric pads, and the chip unit is electrically connected with the circuit board through the plurality of second connecting pads, the plurality of solder balls, and the plurality of first connecting pads.

At the outset, as mentioned in the above “Description of Related Art”, in the prior art, a chip unit is electrically connected with circuit board through plural bonds, wherein the height of the arc formed by the plural bonds is about 10 to 15 mil. In addition, with the existence of the plural bonds, the area of the surface of the chip unit is limited, causing the plural bonds to be easily broken or damaged while the passive element to be directly stacked onto the chip in a three-dimensional packaging method. As a result, the condition of the signal transmission is questioned. Thus, it is still somewhat difficult in the electrical connection by just stacking a passive element onto the chip.

Therefore, in order to obviate the problem of the easily break or damage of the plural bonds, the package structure of the present invention applies the technique of through-silicon via (TSV) package, for replacing the conventional electrical connections with plural bonds. With the TSV, a plurality of conductive vias is directly formed on the chip unit, which penetrates the chip unit. The way to form the plurality of conductive vias is not limited, which can be formed through the laser drill process, the deep reactive-ion etching (DRIB) process, or the cryogenic deep reactive-ion etching (cryogenic DRIE) process. In addition, the technique of ball grid array (BGA) is also applied in the package structure of the present invention, for connecting the chip unit and the circuit board with a plurality of solder balls. Thus, by applying both the TSV and the BGA, the passive element stacked onto the chip unit can be electrically connected with the chip unit, wherein the chip unit can further be electrically connected with the circuit board.

Furthermore, the passive element applied in the package structure of the present invention is not limited to a certain sort of passive elements. In fact, the passive element can be an inductor, a resistor, or a capacitor. Any kind of passive element is suitable for being applied in the package structure of the present invention, for being integrated with the chip by the direct-stacking method.

Besides, the chip unit applied in the package structure of the present invention is a power converting chip, for example, a DC-to-DC converting chip, a DC-to-AC converting chip, an AC-to-AC converting chip, or an AC-to-DC converting chip.

When the passive element applied in the package structure of the present invention is an inductor element, the form of the inductor element is not limited; it is preferably a ferrite power inductor. Due to the intrinsic characteristic of the ferrite power inductor, it will generate magnetic field in the space around the inductor, causing the so-called magnetic leakage. However, when the ferrite power inductor is stacked onto the chip unit directly, the magnetic field in the space around the inductor generated by the inductor may disturb the normal operation of the chip unit, and generate certain level of noise to the chip unit. Moreover, in the package structure with high packaging density, the disturbance caused by the above-mentioned magnetic field is significant, which deteriorate the performance of the chip unit dramatically. For obviating the this problem, the package structure of the present invention applies a novel stack manner of the inductor, and further fills a magnetic material or resin into the ferrite power inductor, for guiding the outer magnetic field (i.e. the magnetic field in the space around the inductor), for minimizing the distribution range of the magnetic flux. The magnetic material mentioned above is not limited; it is preferably composed of a ferromagnetism material or a ceramic-ferromagnetism material.

With the above description, it can be understood that the package structure of the present invention is a stacking structure, which comprises: (from bottom to top): a circuit board, a plurality of first connecting pads, a plurality of solder balls, a plurality of second connecting pads, a chip unit, and a passive element. In the package structure of the present invention, the height of the package structure is between 1 mm and 2 mm, in accordance with the trend of thin package.

Further, in the package structure of the present invention, the plurality of solder balls is preferably composed of tin. Besides, in the package structure of the present invention, the plurality of conductive vias is filled with conductive material or other element that is electrical-conductive. The conductive material mentioned above can be composed of copper, poly silicon, or wolfram.

In addition, in the package structure of the present invention, the passive element can be a film-type passive element, which is directly formed by the technology of microlithography on the non-active surface of the chip unit such as transferring the pattern of the photo-masks of the film-type passive element to the non-active surface of the chip unit with the photolithography process. By using the film-type passive element, the height of the package structure of the present invention can further be reduced. Further, the film-type passive element mentioned above can be a film-type inductor, a film-type capacitor, or a film-type resistor, but preferably a film-type inductor. What should noticed here is, the film-type passive element can be electrically connected with the above-mentioned the plurality of third connecting pads, or the above-mentioned the plurality of conductive vias, when none of the plurality of third connecting pads is required to be disposed on the non-active surface of the chip unit.

It is another object of the present invention to provide the method for manufacturing a package structure which comprises: (A) providing a circuit board having a first surface, where a plurality of first connecting pads being disposed thereon; (B) providing a chip unit having an active surface, a non-active surface and a plurality of conductive vias, while a plurality of second connecting pads and a plurality of electric pads being disposed on the active surface, and a plurality of third connecting pads being disposed on the non-active surface; wherein the plurality of conductive vias penetrates the chip unit and is electrically connected with the plurality of third connecting pads and the plurality of electric pads respectively; (C) connecting the plurality of first connecting pads and the plurality of second connecting pads with a plurality of solder balls; and (D) providing a passive element disposed on the non-active surface of the chip unit, while the passive element being electrically connected with the plurality of third connecting pads.

At the outset, as mentioned in the above “Description of Related Art”, in the prior art, a chip unit is electrically connected with circuit board through plural bonds, wherein the height of the arc formed by the plural bonds is about 10 to 15 mil. In addition, with the existence of the plural bonds, the area of the surface of the chip unit is limited, causing the plural bonds to be easily broken or damaged while the passive element to be directly stacked onto the chip in a three-dimensional packaging method. As a result, the condition of the signal transmission is questioned. Thus, it is still somewhat difficult in the electrical connection by just stacking a passive element onto the chip.

Therefore, in order to obviate the problem of the easily break or damage of the plural bonds, the method for manufacturing a package structure of the present invention applies the technique of through-silicon via (TSV) package, for replacing the conventional electrical connections with plural bonds. With the TSV, a plurality of conductive vias is directly formed on the chip unit, which penetrates the chip unit. In addition, the technique of ball grid array (BGA) is also applied in the method for manufacturing a package structure of the present invention, for connecting the chip unit and the circuit board with a plurality of solder balls. Thus, by applying both the TSV and the BGA, the passive element stacked onto the chip unit can be electrically connected with the chip unit, wherein the chip unit can further be electrically connected with the circuit board.

Furthermore, the passive element applied in the step (D) of the method for manufacturing a package structure of the present invention is not limited to a certain sort of passive elements. In fact, the passive element can be an inductor, a resistor, or a capacitor. Any kind of passive element is suitable for being applied in the method for manufacturing a package structure of the present invention, for being integrated with the chip by the direct-stacking method.

Besides, the chip unit applied in the step (C) of the method for manufacturing a package structure of the present invention is a power converting chip, for example, a DC-to-DC converting chip, a DC-to-AC converting chip, an AC-to-AC converting chip, or an AC-to-DC converting chip.

When the passive element applied in the method for manufacturing a package structure of the present invention is an inductor element, the form of the inductor element is not limited; it is preferably a ferrite power inductor. Due to the intrinsic characteristic of the ferrite power inductor, it will generate magnetic field in the space around the inductor, causing the so-called magnetic leakage. However, when the ferrite power inductor is stacked onto the chip unit directly, the magnetic field in the space around the inductor generated by the inductor may disturb the normal operation of the chip unit, and generate certain level of noise to the chip unit. Moreover, in the package structure with high packaging density, the disturbance caused by the above-mentioned magnetic field is significant, which deteriorate the performance of the chip unit dramatically. For obviating the this problem, the method for manufacturing a package structure of the present invention applies a novel stack manner of the inductor, and further fills a magnetic material or resin into the ferrite power inductor, for guiding the outer magnetic field (i.e. the magnetic field in the space around the inductor), for minimizing the distribution range of the magnetic flux. The magnetic material mentioned above is not limited; it is preferably composed of a ferromagnetism material or a ceramic-ferromagnetism material.

With the above description, it can be understood that the package structure manufactured by the method of the present invention is a stacking structure, which comprises: (from bottom to top): a circuit board, a plurality of first connecting pads, a plurality of solder balls, a plurality of second connecting pads, a chip unit, and a passive element. In the package structure manufactured by the method of the present invention, the height of the package structure is between 1 mm and 2 mm, in accordance with the trend of thin package.

Further, in the package structure manufactured by the method of the present invention, the plurality of solder balls is preferably composed of tin. Besides, in the package structure manufactured by the method of the present invention, the plurality of conductive vias is filled with conductive material or other element that is electrical-conductive. The conductive material mentioned above can be composed of copper, poly silicon, or wolfram.

### BRIEF DESCRIPTION OF THE DRAWINGS

FIG. 1A is a perspective view displaying the first defect of a conventional three-dimensional package structure.

FIG. 1B is a perspective view displaying the second defect of a conventional three-dimensional package structure.

FIG. 1C is a perspective view of displaying the third defect of a conventional three-dimensional package structure.

FIG. 2 is a perspective view displaying the package structure according to the first embodiment of the present invention.

FIG. 3 is a perspective view displaying the package structure according to the second embodiment of the present invention.

FIG. 4 is a perspective view displaying the package structure according to the third embodiment of the present invention.

FIG. 5A is a perspective view displaying the package structure according to the fourth embodiment of the present invention.

FIG. 5B is a top view of the package structure shown in FIG. 5A.

FIG. 6A to FIG. 6D are figures displaying the process of the method for manufacturing a package structure according to the fifth embodiment of the present invention.

FIG. 7 is the flowchart of the method for manufacturing a package structure according to the fifth embodiment of the present invention.

### DETAILED DESCRIPTION OF THE PREFERRED EMBODIMENT

The present invention has been described in an illustrative manner, and it is to be understood that the terminology used in this specification is intended to be in the nature of description rather than of limitation. Many modifications and variations of the present invention are possible in light of the above teachings. Therefore, it is to be understood that within the scope of the appended claims, the invention may be practiced otherwise than as specifically described.

The solutions for solving the problem raised in the implementation of the package structure of the present invention would be provided in the following portion of this specification. With the description provided below, it can be easily understood that both of the package structure and the method for manufacturing a package structure of the present invention can actually obviate the problems encountered in the implementation of the conventional three-dimensional package structure. Before starting to described the package structure and the method for manufacturing a package structure of the present invention in detail, please kindly refer to the “Description of Related Art” portion of this specification, for a better understanding on the skill level of the conventional package structure. The main object of the present invention is to provide a package structure capable of minimizing the area of the circuit board used for packaging.

The most efficient way to obviate the drawbacks of the conventional package structure is to change the way of packaging. For example, by directly integrating the passive element with the power converting chip, the circuit board area occupied by the passive element can be reduced. The above-mentioned integration of the passive element with the power converting chip is actually the stacking the passive element directly onto the power converting chip. However, in the implementation of this three-dimensional package, a lot of problems raises, which will be described below, in accompany with the proper figures.

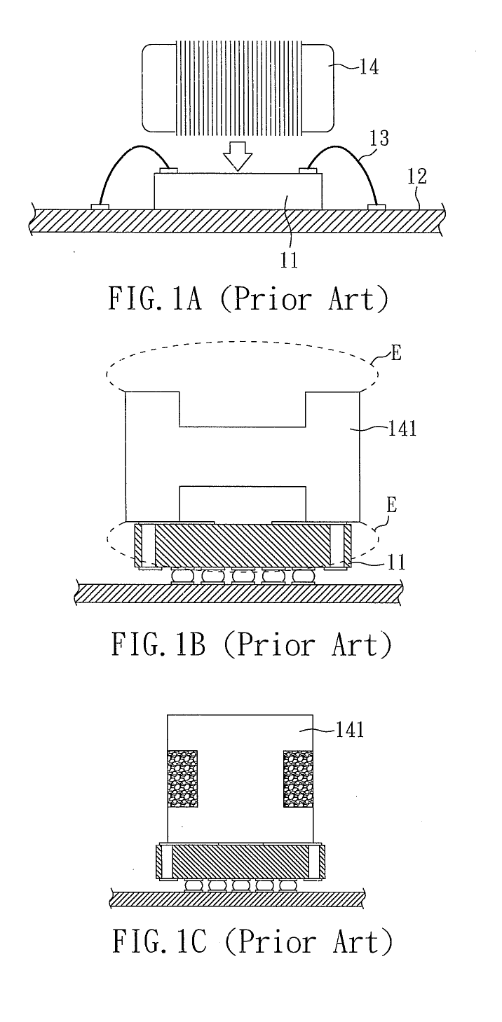

Please refers to FIG. 1A, which is a perspective view displaying the first defect of a conventional three-dimensional package structure, a chip unit 11 is disposed on a circuit board 12 by the surface mount technology (SMT). Further, since the volume of the passive element 14 is large, it is difficult to integrate the passive element 14 with the chip unit 11 by directly stacking the passive element 14 onto the chip unit 11. Besides, even though the passive element 14 can be stacked onto the chip unit 11, the electrical connection of passive element 14 is still difficult to build up. Moreover, as the chip unit 11 is electrically connected with the circuit board 12 through the bond 13, the bond 13 will be easily damaged or broken by the press of the passive element 14, when the passive element 14 is directly stacked onto the chip unit 11. Therefore, the passive element cannot be stacked onto the chip unit for achieving the objects of the present invention. Please refer to FIG. 1B, which is a perspective view displaying the second defect of a conventional three-dimensional package structure. The defect is raised when the passive element 14 of FIG. 1A is an inductor element 141. It should be noticed that, identical elements in both FIG. 1B and FIG. 1A will be given the same element symbols in both figures, for simplifying the description and improving the comprehension of the conventional package structure.

As shown in FIG. 1B, the inductor element 141 is stacked onto the chip unit 11. Besides, the inductor element 141 generates a magnetic field in the space around the inductor element 141, which causes the so-called magnetic leakage. In addition, as shown in FIG. 1B, a magnetic force line E is used for representing the magnetic field generated outside the inductor element 141. However, since the magnetic force line E at the position below the inductor element 141 is overlapped with some portion of the chip unit 11, the magnetic field will disturb the normal operation of the chip unit 11, and generate certain level of noise to the chip unit 11. Moreover, since the manufacturing processes used in chip manufacturing has been improved into the generation of nanometer-order, the above-mentioned magnetic leakage will cause an unnegligible disturbance on the operation of the chip unit 11, which may cause the chip unit 11 to shut down.

Please refer to FIG. 1C, which is a perspective view of displaying the third defect of a conventional three-dimensional package structure. The defect shown in this figure is: even though the passive element can be stacked onto the chip unit directly and vertically, after obviating the problems described above, the total height of the package structure is still too large for certain kind of application. Besides, this vertically disposing manner of the passive element will cause the package structure being contrary to the trend of thin package popular in the nowadays package industry.

The solution for fixing these three kinds of defect, which has been described in accompany with FIG. 1A, FIG. 1B, and FIG. 1C, will be described in the following embodiments.

### Embodiment 1

### Applying Both the Technique of Through-Silicon Via and the Technique of Ball Grid Array

Please refers to FIG. 1A, which is a perspective view displaying the first defect of a conventional three-dimensional package structure, a chip unit 11 is disposed on a circuit board 12 by the surface mount technology (SMT). Further, since the volume of the passive element 14 is large, it is difficult to integrate the passive element 14 with the chip unit 11 by directly stacking the passive element 14 onto the chip unit 11. Besides, even though the passive element 14 can be stacked onto the chip unit 11, the electrical connection of passive element 14 is still difficult to build up. Moreover, as the chip unit 11 is electrically connected with the circuit board 12 through the bond 13, the bond 13 will be easily damaged or broken by the press of the passive element 14, when the passive element 14 is directly stacked onto the chip unit 11.

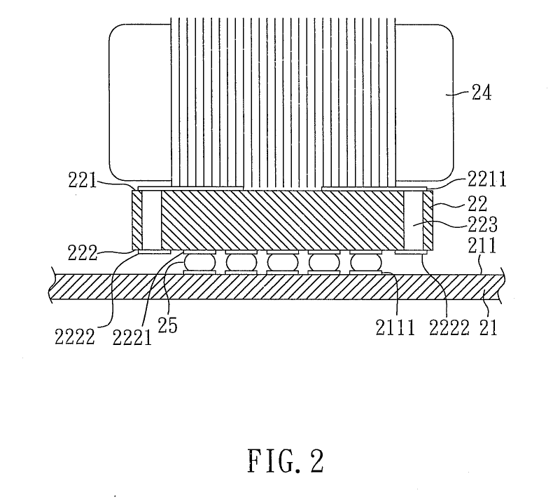

For fixing the defect mentioned above, please refer to FIG. 2, which is a perspective view displaying the package structure according to the first embodiment of the present invention. As shown in FIG. 2, the package structure of the present invention comprises: a circuit board 21, a chip unit 22, a plurality of solder balls 25, and a passive element 24. Wherein, the circuit board 21 has a first surface 211, where a plurality of first connecting pads 2111 being disposed thereon. In addition, the chip unit 22 has an active surface 222, and a non-active surface 221, and a plurality of conductive vias 223, wherein a plurality of second connecting pads 2221 and a plurality of electric pads 2222 are disposed on the active surface 222. Besides, a plurality of third connecting pads 2211 is disposed on the non-active surface 221 of the chip unit 22. The plurality of conductive vias 223 is disposed on the chip unit 22 and penetrated the chip unit 22. The plurality of solder balls 25 is electrically connected with the plurality of first connecting pads 2111 and the plurality of second connecting pads 2221. At final, the passive element 24 is disposed on the plurality of third connecting pads 2211 disposed on the non-active surface 221 of the chip unit 22.

In this embodiment, the plurality of conductive vias 223 is filled with conductive material. The passive element 24 is electrically connected with the chip unit 22 through the plurality of third connecting pads 2211, the plurality of conductive vias 223, and the plurality of electric pads 2222. The chip unit 22 is electrically connected with the circuit board 21 through the plurality of second connecting pads 2221, the plurality of solder balls 25, and the plurality of first connecting pads 2111.

By comparing FIG. 2 with FIG. 1A, it can be understood that the defect shown in FIG. 1A can be solved by replacing the bonds with the method of applying both the technique of Through-Silicon Via and the technique of Ball Grid Array.

### Embodiment 2

### The Passive Element is an Inductor Element

Please refer to FIG. 1B, which is a perspective view displaying the second defect of a conventional three-dimensional package structure. The inductor element 141 is stacked onto the chip unit 11. Besides, the inductor element 141 generates a magnetic field in the space around the inductor element 141, which causes the so-called magnetic leakage. In addition, as shown in FIG. 1B, a magnetic force line E is used for representing the magnetic field generated outside the inductor element 141. However, since the magnetic force line E at the position below the inductor element 141 is overlapped with some portion of the chip unit 11, the magnetic field will disturb the normal operation of the chip unit 11, and generate certain level of noise to the chip unit 11. Moreover, since the manufacturing processes used in chip manufacturing has been improved into the generation of nanometer-order, the above-mentioned magnetic leakage will cause an unnegligible disturbance on the operation of the chip unit 11, which may cause the chip unit 11 to shut down.

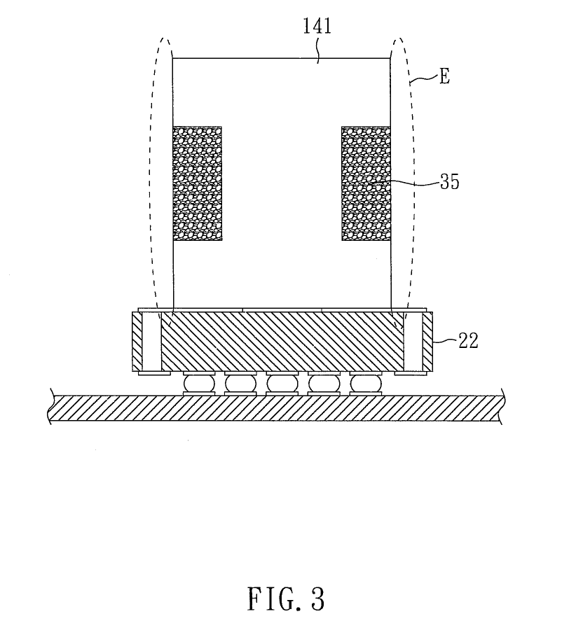

For fixing the defect mentioned above, please refer to FIG. 3, which is a perspective view displaying the package structure according to the second embodiment of the present invention. As shown in FIG. 3, the stacking manner of the inductor element 141 is perpendicular to that of the inductor element 141 shown in FIG. 1B. As a result, the magnetic field generated by the inductor element 141 is located at the left-hand side and the right-hand side of the inductor element 141, as represented by the magnetic force line E. FIG. 3. Thus, the disturbance on the normal operation of the chip unit 22, caused by the magnetic field, may be eliminated significantly.

Besides, for further limiting the distribution range of the magnetic field, a magnetic material 35 or resin is filled inside the inductor element 141 of the package structure of the present invention, since the magnetic material 35 or resin is able to guide the outer magnetic field at a certain level. The magnetic material to be filled is not limited; it can be composed of a ferromagnetism material or a ceramic-ferromagnetism material.

By comparing FIG. 3 with FIG. 1B, the disturbance on the normal operation of the chip unit, caused by the magnetic leakage, may be minimizing through the change of the stacking manner of the inductor element of the package structure of the present invention.

### Embodiment 3

### Applying a Film-Type Passive Element

Please refer to FIG. 1C, which is a perspective view of displaying the third defect of a conventional three-dimensional package structure. The defect shown in this figure is: even though the passive element can be stacked onto the chip unit directly and vertically, after obviating the problems described above, the total height of the package structure is still too large for certain kind of application. Besides, this vertically disposing manner of the passive element will cause the package structure being contrary to the trend of thin package popular in the nowadays package industry.

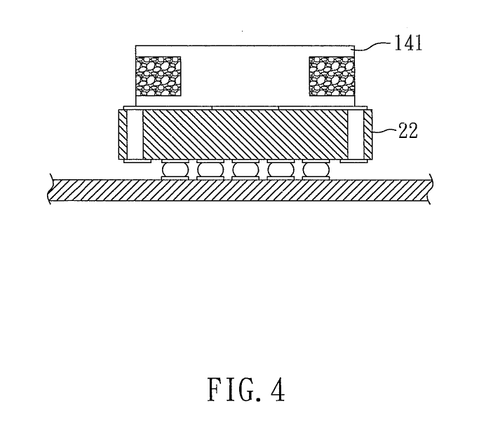

For fixing the defect mentioned above, please refer to FIG. 4, which is a perspective view displaying the package structure according to the third embodiment of the present invention. As shown in FIG. 4, an inductor element 141 is stacked onto the chip unit 22 in a stacking manner similar to that shown in the previous embodiment, which is Embodiment 2. However, the inductor element 141 being stacked here is a thin-type inductor element, whose height is less than the height of the inductor element used in the embodiment 2. In some cases, the height of this thin-type inductor element can be less than 1 mm. Thus, the height of the entire package structure can be reduced to be in the range between 1 mm and 2 mm.

### Embodiment 4

### Film-Type Inductor Formed by Microlithography

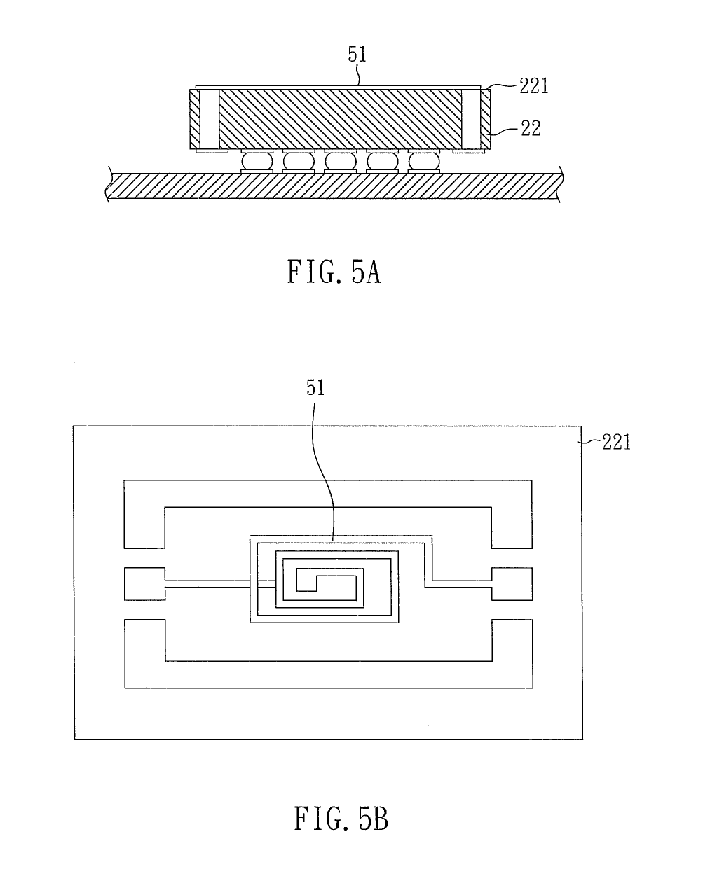

Please refer to FIG. 5A and FIG. 5B, wherein FIG. 5A is a perspective view displaying the package structure according to the fourth embodiment of the present invention. Besides, FIG. 5B is a top view of the package structure shown in FIG. 5A.

The package structure in this embodiment is further derived from the previous embodiments i.e. Embodiment 2 and Embodiment 3. In this embodiment, the thickness of the package structure is further reduced. As shown in FIG. 5B, a film-type inductor 51 is formed on the non-active surface 221 of the chip unit 22, by the technique of the microlithography. In this embodiment, the microlithography process is the photolithography process, which is able to transfer the pattern of photo-masks of the film-type inductor, to the non-active surface 221 of the chip unit 22.

The thickness of the film-type inductor formed by the photolithography process in this embodiment is less than 0.3 mm. As a result, the thickness of the film-type inductor in this present embodiment is much less than that of the inductor element used in the Embodiment 2 and the Embodiment 3. Which means, the height of the package structure in this embodiment is further decreased. What should noticed here is, the film-type passive element can be electrically connected with the above-mentioned the plurality of third connecting pads, or the above-mentioned the plurality of conductive vias, when none of the plurality of third connecting pads is required to be disposed on the non-active surface of the chip unit.

Further, the microlithography process used for forming the film-type inductor on the non-active surface of the chip unit is not limited to the photolithography process; it can be any kind of microlithography process suitable for forming the film-type inductor.

### Embodiment 5

### The Method for Manufacturing

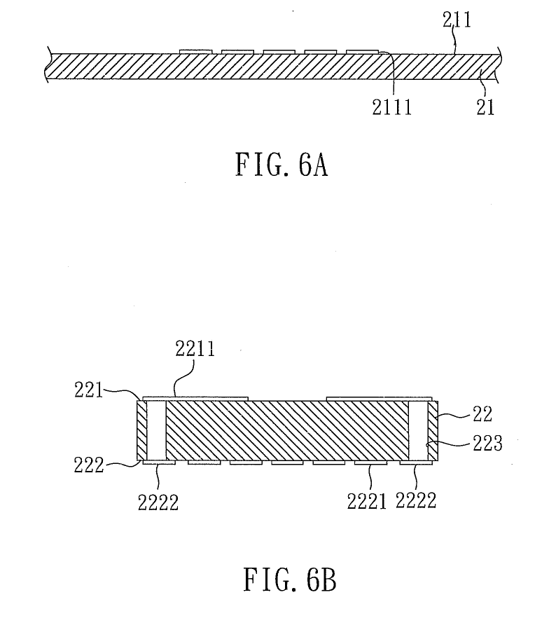

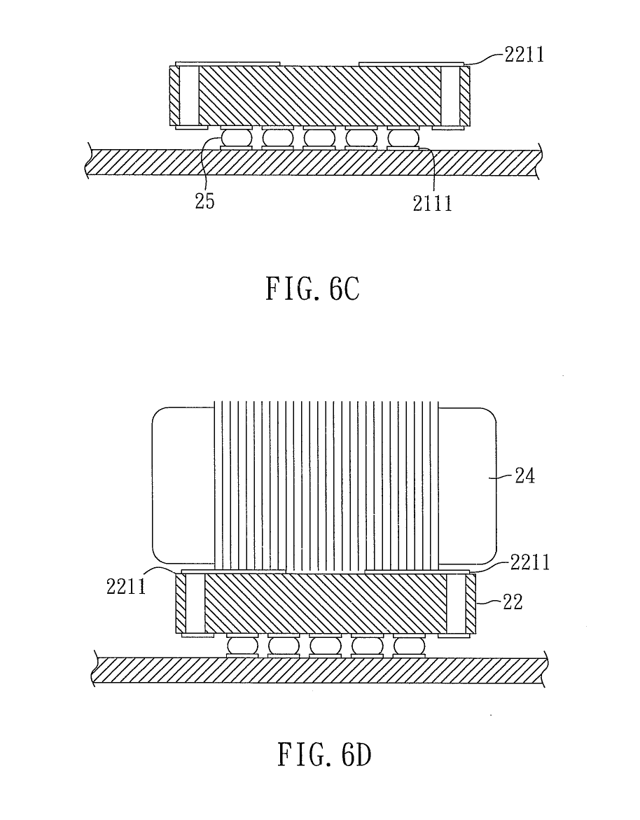

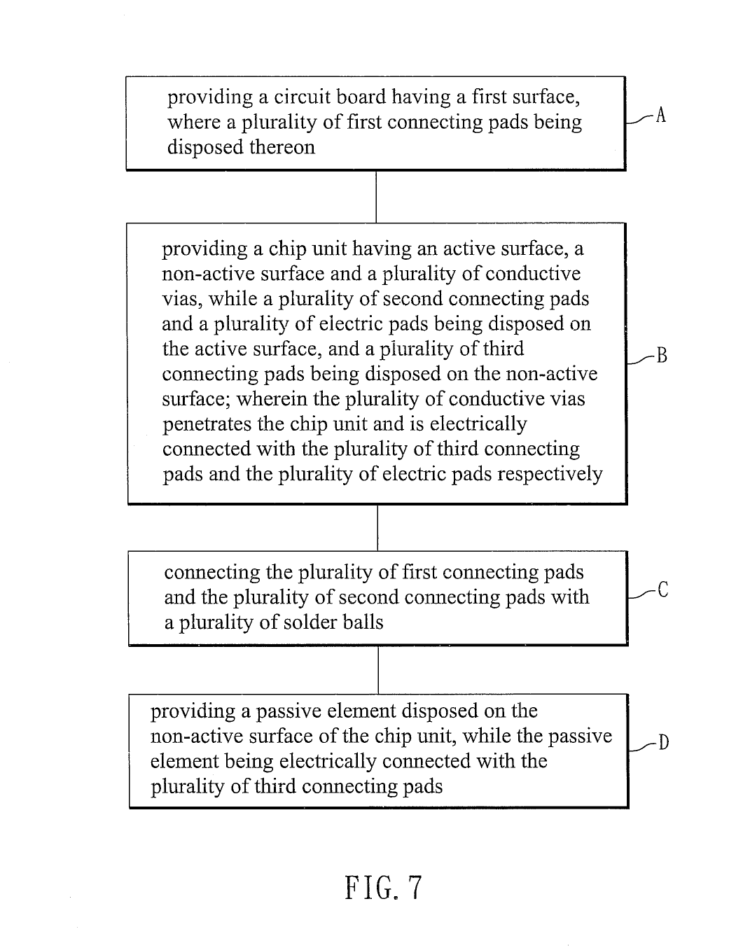

Please refer to FIG. 6A to FIG. 6D, and FIG. 7, for understanding the method for manufacturing a package structure of the present invention. Wherein, FIG. 6A to FIG. 6D are figures displaying the process of the method for manufacturing a package structure according to the fifth embodiment of the present invention, and FIG. 7 is the flowchart of the method for manufacturing a package structure according to the fifth embodiment of the present invention.

As shown in FIG. 6A and FIG. 7, at first, the step (A) of the method is: providing a circuit board 21 having a first surface 211, where a plurality of first connecting pads 2111 is disposed thereon.

Then, as shown in FIG. 6B and FIG. 7, the step (B) of the method is: providing a chip unit 22 having an active surface 222, a non-active surface 221 and a plurality of conductive vias 223, while a plurality of second connecting pads 2221 and a plurality of electric pads 2222 being disposed on the active surface 222, and a plurality of third connecting pads 2211 being disposed on the non-active surface 221, wherein the plurality of conductive vias 223 penetrates the chip unit 22 and is electrically connected with the plurality of third connecting pads 2211 and the plurality of electric pads 2222 respectively.

Then, as shown in FIG. 6C and FIG. 7, the step (C) of the method is: connecting the plurality of first connecting pads 2111 and the plurality of second connecting pads 2221 with a plurality of solder balls 25.

At last, as shown in FIG. 6D and FIG. 7, the step (D) of the method is: providing a passive element 24 being disposed on the non-active surface 221 of the chip unit 22, while the passive element 22 being electrically connected with the plurality of third connecting pads 2211.

At the outset, as mentioned in the above “Description of Related Art”, in the prior art, a chip unit is electrically connected with circuit board through plural bonds, wherein the height of the arc formed by the plural bonds is about 10 to 15 mil. In addition, with the existence of the plural bonds, the area of the surface of the chip unit is limited, causing the plural bonds to be easily broken or damaged while the passive element to be directly stacked onto the chip in a three-dimensional packaging method. As a result, the condition of the signal transmission is questioned. Thus, it is still somewhat difficult in the electrical connection by just stacking a passive element onto the chip.

Therefore, in order to obviate the problem of the easily break or damage of the plural bonds, the package structure of the present invention applies the technique of through-silicon via (TSV) package, for replacing the conventional electrical connections with plural bonds. With the TSV, a plurality of conductive vias is directly formed on the chip unit, which penetrates the chip unit. In addition, the technique of ball grid array (BGA) is also applied in the package structure of the present invention, for connecting the chip unit and the circuit board with a plurality of solder balls.

Furthermore, in the step (D), the passive element applied in the method for manufacturing a package structure of the present invention is not limited to a certain sort of passive elements. In fact, the passive element can be an inductor, a resistor, or a capacitor. Any kind of passive element is suitable for being applied in the method for manufacturing a package structure of the present invention, for being integrated with the chip by the direct-stacking method.

Besides, in the step (B), the chip unit applied in the method for manufacturing a package structure of the present invention is a power converting chip, for example, a DC-to-DC converting chip, a DC-to-AC converting chip, an AC-to-AC converting chip, or an AC-to-DC converting chip. When the passive element applied in the package structure of the present invention is an inductor element, the form of the inductor element is not limited; it is preferably a ferrite power inductor. Due to the intrinsic characteristic of the ferrite power inductor, it will generate magnetic field in the space around the inductor, causing the so-called magnetic leakage. However, when the ferrite power inductor is stacked onto the chip unit directly, the magnetic field in the space around the inductor generated by the inductor may disturb the normal operation of the chip unit, and generate certain level of noise to the chip unit. Moreover, in the package structure with high packaging density, the disturbance caused by the above-mentioned magnetic field is significant, which deteriorate the performance of the chip unit dramatically. For obviating the this problem, the package structure of the present invention applies a novel stack manner of the inductor, and further fills a magnetic material or resin into the ferrite power inductor, for guiding the outer magnetic field (i.e. the magnetic field in the space around the inductor), for minimizing the distribution range of the magnetic flux. The magnetic material mentioned above is not limited; it is preferably composed of a ferromagnetism material or a ceramic-ferromagnetism material.

With the, above description, it can be understood that the package structure of the present invention is a stacking structure, which comprises: (from bottom to top): a circuit board, a plurality of first connecting pads, a plurality of solder balls, a plurality of second connecting pads, a chip unit, and a passive element. In the package structure of the present invention, the height of the package structure is between 1 mm and 2 mm, in accordance with the trend of thin package.

Further, in the package structure of the present invention, the plurality of solder balls is preferably composed of tin. Besides, in the package structure of the present invention, the plurality of conductive vias is filled with conductive material or other element that is electrical-conductive. The conductive material mentioned above can be composed of copper, poly silicon, or wolfram.

Although the present invention has been explained in relation to its preferred embodiment, it is to be understood that many other possible modifications and variations can be made without departing from the spirit and scope of the invention as hereinafter claimed.

What is claimed is:

1. A package structure, comprising:
a circuit board having a first surface, where a plurality of first connecting pads being disposed thereon;
a chip unit having an active surface, a non-active surface and a plurality of conductive vias, while a plurality of second connecting pads and a plurality of electric pads being disposed on the active surface, and a plurality of third connecting pads being disposed on the non-active surface; wherein the plurality of conductive vias penetrates the chip unit and is electrically connected with the plurality of second connecting pads and the plurality of third connecting pads respectively;
a plurality of solder balls electrically connected with the plurality of first connecting pads and the plurality of second connecting pads; and
a passive element being disposed on the non-active surface of the chip unit, and electrically connected with the plurality of third connecting pads;
wherein the passive element is electrically connected with the chip unit through the plurality of third connecting pads, the plurality of conductive vias, and the plurality of electric pads, and the chip unit is electrically connected with the circuit board through the plurality of second connecting pads, the plurality of solder balls, and the plurality of first connecting pads.

2. The package structure as claimed in claim 1, wherein the passive element is an inductor element, a resistor element, or a capacitor element.

3. The package structure as claimed in claim 2, wherein the inductor element is a ferrite power inductor.

4. The package structure as claimed in claim 3, wherein the inductor element is filled with a magnetic material or resin.

5. The package structure as claimed in claim 4, wherein the magnetic material is composed of a ferromagnetism material or a ceramic-ferromagnetism material.

6. The package structure as claimed in claim 1, wherein the chip unit is a power converting chip, and the power converting chip is a DC-to-DC converting chip, a DC-to-AC converting chip, an AC-to-AC converting chip, or an AC-to-DC converting chip.

7. The package structure as claimed in claim 1, wherein the material of the plurality of solder balls is composed of tin or other kind of metallic material.

8. The package structure as claimed in claim 1, wherein the height of the package structure is between 1 mm and 2 mm.

9. The package structure as claimed in claim 1, wherein the plurality of conductive vias is formed by the technique of through-silicon via package.

10. A method for manufacturing a package structure, comprising:
(A) providing a circuit board having a first surface, where a plurality of first connecting pads being disposed thereon;
(B) providing a chip unit having an active surface, a non-active surface and a plurality of conductive vias, while a plurality of second connecting pads and a plurality of electric pads being disposed on the active surface, and a plurality of third connecting pads being disposed on the non-active surface; wherein the plurality of conductive vias penetrates the chip unit and is electrically connected with the plurality of third connecting pads and the plurality of electric pads respectively;
(C) connecting the plurality of first connecting pads and the plurality of second connecting pads with a plurality of solder balls; and
(D) providing a passive element disposed on the non-active surface of the chip unit, while the passive element being electrically connected with the plurality of third connecting pads.

11. The method as claimed in claim 10, wherein in step (D), the passive element is an inductor element, a resistor element, or a capacitor element.

12. The method as claimed in claim 11, wherein the inductor element is a ferrite power inductor.

13. The method as claimed in claim 12, wherein the inductor element is filled with a magnetic material or resin.

14. The method as claimed in claim 13, wherein the magnetic material is composed of a ferromagnetism material or a ferrimagnetism material.

15. The method as claimed in claim 10, wherein in step (B), the chip unit is a power converting chip, and the power converting chip is a DC-to-DC converting chip, a DC-to-AC converting chip, an AC-to-AC converting chip, or an AC-to-DC converting chip.

16. The method as claimed in claim 10, wherein the material of the plurality of solder balls is composed of tin or other kind of metallic material.

17. The method as claimed in claim 10, wherein the height of the package structure manufactured by the method is between 1 mm and 2 mm.

18. The method as claimed in claim 10, wherein in step (B), the plurality of conductive vias is formed by the technique of through-silicon via package.

19. A package structure, comprising:
a circuit board having a first surface, where a plurality of first connecting pads being disposed thereon;
a chip unit having an active surface, a non-active surface, and a plurality of conductive vias, while a plurality of second connecting pads and a plurality of electric pads being disposed on the active surface, wherein the plurality of conductive vias penetrates the chip unit;
a plurality of solder balls electrically connected with the plurality of first connecting pads and the plurality of second connecting pads; and
a film-type passive element being formed on the non-active surface of the chip unit, and being electrically connected with the plurality of conductive vias of the chip unit;
wherein the film-type passive element is electrically connected with the chip unit through the plurality of conductive vias and the plurality of electric pads, and the chip unit is electrically connected with the circuit board through the plurality of second connecting pads, the plurality of solder balls, and the plurality of first connecting pads.

20. The package structure as claimed in claim 19, wherein the film-type passive element is composed of a ferromagnetism material.
